(19) United States
(12) Patent Application Publication
(10) Pub. No.: US 2026/0079787 A1
(43) Pub. Date: Mar. 19, 2026

(54) ERROR CORRECTION DEVICE AND MEMORY DEVICE INCLUDING THE SAME

(71) Applicant: SK hynix Inc., Gyeonggi-do (KR)

(72) Inventors: Seong Yoon KANG, Gyeonggi-do (KR); Mun Seon JANG, Gyeonggi-do (KR); Sang Uhn CHA, Gyeonggi-do (KR); Dong Hee HAN, Gyeonggi-do (KR)

(21) Appl. No.: 18/991,732

(22) Filed: Dec. 23, 2024

(30) Foreign Application Priority Data
Sep. 13, 2024 (KR) 10-2024-0125379

(51) Int. Cl. G06F 11/10

(52) U.S. Cl. CPC G06F 11/1016; G06F 11/1068

(57) ABSTRACT

A memory device includes a memory core including a plurality of cell blocks grouped into a plurality of cell groups, each cell group including adjacent cell blocks disposed in a row direction and sharing sub-word line drivers with adjacent cell groups; and an error correction circuit configured to, during a read operation, correct an error of main data in units of symbols by calculating the main data and an error correction code, which are read from the memory core, with a check matrix, each unit of symbols including data output from one cell group, or data output from cell blocks disposed at both ends of two adjacent cell groups based on a sub-word line driver shared between the two adjacent cell groups.

### CROSS-REFERENCE TO RELATED APPLICATION

The present application claims the benefit of Korean Patent Application No. 10-2024-0125379, filed on Sep. 13, 2024, which is incorporated herein by reference in its entirety.

### BACKGROUND

### 1. Field

Various embodiments of the present disclosure relate to a semiconductor design technology, and more particularly, to a memory device performing an error correction operation.

### 2. Description of the Related Art

In the early days of the semiconductor memory industry, a plurality of original good dies having no defective memory cells in a memory chip having passed through a semiconductor manufacturing process have been distributed on a wafer. However, as the capacity of a memory device gradually increased, it has become difficult to produce a memory having no defective memory cells. At the present time, there is no probability that such a memory will be manufactured. One way to overcome such a situation is a method of repairing defective memory cells of a memory with redundancy memory cells. As another way, a method of error correction of data of memory cells using an error correction circuit embedded in a memory device and/or a memory controller is used.

### SUMMARY

Embodiments of the present disclosure are directed to a memory device capable of expanding an error correction capability according to an error occurrence tendency.

In accordance with an embodiment of the present disclosure, a memory device includes a memory core including a plurality of cell blocks grouped into a plurality of cell groups, each cell group including adjacent cell blocks disposed in a row direction and sharing sub-word line drivers with adjacent cell groups; and an error correction circuit configured to, during a read operation, correct an error of main data in units of symbols by calculating the main data and an error correction code, which are read from the memory core, with a check matrix, each unit of symbols including data output from one cell group, or data output from cell blocks disposed at both ends of two adjacent cell groups based on a sub-word line driver shared between the two adjacent cell groups.

In accordance with an embodiment of the present disclosure, a memory device includes a lower chip; and one or more upper chips stacked over the lower chip, wherein each of the upper chips includes: a memory core including a plurality of cell blocks grouped into a plurality of cell groups, each cell group including adjacent cell blocks disposed in a row direction; and an error correction circuit, during a read operation, configured to correct an error of main data in units of symbols by calculating the main data and an error correction code, which are read from the memory core, with a check matrix, each unit of symbols including data output from one cell group, or data output from cell blocks disposed at both ends of two adjacent cell groups.

In accordance with an embodiment of the present disclosure, an error correction device includes a syndrome comparison circuit configured to generate a plurality of sub-syndromes by calculating a first syndrome indicating an error pattern and a check matrix, and generate a plurality of syndrome comparison signals corresponding to each of a plurality of cell blocks by comparing the plurality of sub-syndromes and a second syndrome indicating a location of a symbol containing an error; an error location detector configured to generate an error location signal indicating an error location in units of symbols based on the plurality of syndrome comparison signals, wherein the units of symbols include data output from one cell group among a plurality of cell groups in which adjacent cell blocks are grouped, or data output from cell blocks disposed at both ends of two adjacent cell groups; and an error corrector configured to correct an error of a codeword output from the plurality of cell groups, according to the error location signal.

In accordance with an embodiment of the present disclosure, a memory device includes a memory core; and an error correction circuit, during a read operation, configured to correct an error of main data in units of symbols by calculating the main data and an error correction code, which are read from the memory core, with a check matrix, wherein the check matrix includes: data matrices corresponding to the main data, each data matrix including an upper portion in which two unit matrices are arranged in a first diagonal direction and a lower portion in which two identical Tk companion matrices are arranged in the first diagonal direction, where k values of the Tk companion matrices are different positive integers different from each data matrix; and parity matrices corresponding to the error correction code, each parity matrix including an upper portion in which two unit matrices are arranged in the first diagonal direction and a lower portion in which two unit matrices or two zero matrices are arranged in the first diagonal direction.

According to embodiments of the present disclosure, in a memory device that corrects an error in read data in units of symbols, the memory device may expand the error correction capability by correcting not only an error occurring in one symbol but also an error occurring at both ends of two adjacent symbols. According to embodiments of the present disclosure, the memory device may provide optimized reliability, accessibility, serviceability (RAS) by increasing the error relief capability of the memory controller.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a block diagram illustrating a memory device according to an embodiment of the present disclosure.

FIG. 2 is a detailed configuration diagram illustrating a memory core of FIG. 1, according to an embodiment of the present disclosure.

FIG. 3 is a diagram for describing an occurrence of an error due to a fault of a sub-word line driver in the memory core of FIG. 2, according to an embodiment of the present disclosure.

FIGS. 4A and 4B are diagrams for describing a symbol configuration according to an embodiment of the present disclosure.

FIGS. 5A to 6B are diagrams for describing a configuration of a check matrix used by an ECC engine, according to an embodiment of the present disclosure.

FIGS. 7A to 7C are diagrams for describing a configuration of a check matrix according to an embodiment of the present disclosure.

FIG. 8 is a block diagram illustrating an error correction circuit according to an embodiment of the present disclosure.

FIG. 9 is a diagram for describing first and second syndromes generated in a syndrome generation circuit of FIG. 8, according to an embodiment of the present disclosure.

FIG. 10 is a detailed block diagram illustrating a first multiplier of FIG. 8, according to an embodiment of the present disclosure.

FIG. 11 is a detailed circuit diagram illustrating a syndrome comparator of FIG. 8, according to an embodiment of the present disclosure.

FIG. 12 is a detailed circuit diagram illustrating an error location detector of FIG. 8, according to an embodiment of the present disclosure.

FIG. 13 is a detailed circuit diagram illustrating the error detector of FIG. 12, according to an embodiment of the present disclosure.

FIG. 14 is a table for describing a configuration of a check matrix according to an operation of an error location detector of FIG. 12, according to an embodiment of the present disclosure.

FIGS. 15A and 15B are diagrams illustrating an error correction operation according to an embodiment of the present disclosure.

FIG. 16 is a block diagram illustrating a memory system including a memory module according to an embodiment of the present disclosure.

FIG. 17 is a block diagram illustrating a memory system including a stacked memory device according to an embodiment of the present disclosure.

FIG. 18 is a block diagram illustrating a mobile system including a memory device according to an embodiment of the present disclosure.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit or element intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

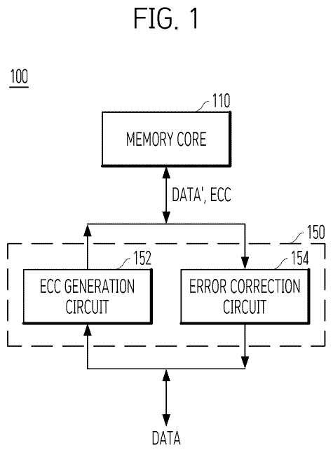

FIG. 1 is a block diagram illustrating a memory device 100 according to an embodiment of the present disclosure. FIG. 1 illustrates only parts of the memory device 100 directly related to data storage and data error correction.

Referring to FIG. 1, the memory device 100 may include a memory core 110 and an error correction code (ECC) engine 150.

The memory core 110 may refer to a region where data is stored within the memory device 100, and may include a memory cell array including a plurality of memory cells for storing data. The plurality of memory cells may be coupled between a plurality of word lines and a plurality of bit lines arranged in an array type. The memory core 110 may further include a row control circuit coupled to the memory cell array through the plurality of word lines to perform row control of the memory cell array, and a column control circuit coupled to the memory cell array through the plurality of bit lines to perform column control of the memory cell array.

The memory core 110 may receive and store data DATA′ and an error correction code ECC from the ECC engine 150 during a write operation. During a read operation, the memory core 110 may transmit stored data DATA′ and the stored error correction code ECC to the ECC engine 150. The data DATA′ may be referred to as user data. The error correction code ECC may be referred to as parity data.

The ECC engine 150 may generate the error correction code ECC by using the data DATA input from an external device (e.g., a memory controller) during a write operation, and may provide the main data DATA′ and the error correction code ECC to the memory core 110. The ECC engine 150 may correct an error of the main data DATA′ read from the memory core 110 using the error correction code ECC read from the memory core 110 during a read operation and output error-corrected data DATA to the memory controller. In an embodiment, the ECC engine 150 may have an ability to correct an error occurring in the main data DATA′ in units of symbols. That is, the ECC engine 150 may correct an error in one symbol regardless of the number of error bits. A Reed-Solomon (RS) method may be used for error correction in units of symbols. The ECC engine 150 may perform an RS encoding operation that generates an error correction code ECC using a parity check matrix (hereinafter, referred to as a “check matrix”) and an RS decoding operation that corrects an error using the error correction code ECC. In an embodiment, a symbol may represent data including a certain number of bits as a basic unit of RS encoding and RS decoding operations. For example, one symbol may include 8-bit or 16-bit data.

The ECC engine 150 may include an ECC generation circuit 152 and an error correction circuit 154.

The ECC generation circuit 152 may generate the error correction code ECC by using the data DATA input from the memory controller during a write operation, that is, during an encoding operation of the ECC engine 150. The ECC generation circuit 152 may generate the error correction code ECC by calculating the data DATA with a check matrix. Since the error correction code ECC is generated and the error correction operation is not performed during the write operation, the data DATA input to the ECC generation circuit 152 may be the same as the main data DATA′ output from the ECC generation circuit 152 during the write operation. For reference, the check matrix to be described later may be composed of H matrices in units of symbols.

The error correction circuit 154 may correct an error of the main data DATA′ using the error correction code ECC read from the memory core 110 during a read operation, that is, a decoding operation of the ECC engine 150. The error correction circuit 154 may calculate the error of the main data DATA′ and the error correction code ECC read from the memory core 110, with a check matrix, and correct the error of the main data DATA′ in units of symbols. Here, correcting an error may mean detecting the error of the main data DATA′ and correcting the error when the error is detected.

Depending on an embodiment, the ECC engine 150 may be provided anywhere on a path through which data is transmitted during write and read operations. During the write operation, write data may be transmitted from the memory controller to the memory core 100, and during the read operation, read data may be transmitted from the memory core 100 to the memory controller. The ECC engine 150 may be located anywhere on a path through which the write data and the read data are transmitted. For example, the ECC engine 150 may be provided inside the memory controller or within the memory device 100. Alternatively, the ECC engine 150 may be provided inside a buffer chip that buffers data between the memory controller and the memory device 100.

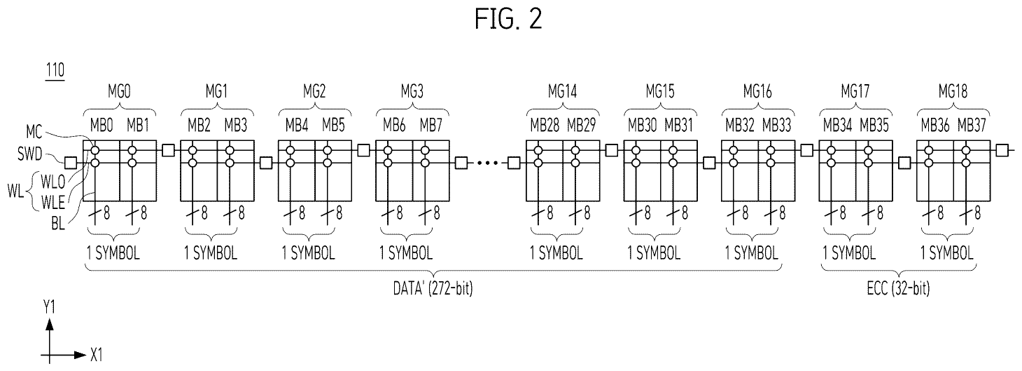

FIG. 2 is a detailed configuration diagram illustrating the memory core 110 of FIG. 1, according to an embodiment of the present disclosure.

Referring to FIG. 2, a memory cell array of the memory core 110 is illustrated. The memory cell array may include a plurality of memory cells MC coupled between a plurality of word lines WL and a plurality of bit lines BL, respectively, and arranged in an array type. The plurality of word lines WL may extend in a first direction X1 (e.g., a row direction) and may be sequentially arranged in a second direction Y1 (e.g., a column direction) perpendicular to the row direction. The plurality of bit lines BL may extend in the column direction Y1 and may be sequentially arranged in the row direction X1.

The memory cell array may be divided into a plurality of memory blocks (hereinafter, referred to as “cell blocks”) each including a plurality of memory cells MC. For example, a plurality of cell blocks may include first to 38-th cell blocks MB0 to MB37. In FIG. 2, only the cell blocks MB0 to MB37 disposed in the row direction X1 are illustrated, but the cell blocks may be arranged in an array type in the row direction X1 and the column direction Y1. In an embodiment, a cell block may be defined as a set of memory cells that share the word lines WL and the bit lines BL and are arranged in the same form.

The plurality of cell blocks MB0 to MB37 disposed in the row direction X1 may be divided into a plurality of cell groups MG0 to MG18. A predetermined number (e.g., two) of adjacent cell blocks among the first to 38-th cell blocks MB0 to MB37 may form a single cell group. For example, the first and second cell blocks MB0 and MB1 form a first cell group MG0, and the third and fourth cell blocks MB2 and MB3 form a second cell group MG1, and in this way, the 37th and 38-h cell blocks MB36 and MB37 may form a nineteenth cell group MG18.

A plurality of sub-word line drivers SWD may be disposed between the cell groups MG0 to MG18 disposed in the row direction X1. Lines extending to the left and right sides of the sub-word line drivers SWD may represent word lines WL (or sub-word lines). Actually, a much larger number of sub-word line drivers and word lines exist, but herein, only a part of the sub-word line drivers and word lines are shown to illustrate the simple structure.

Each of the cell groups MG0 to MG18 may include odd-numbered word lines (hereinafter, referred to as “first word lines WLO”) and even-numbered word lines (hereinafter, referred to as “second word lines WLE”) extending in the row direction X1 and alternating with each other in the column direction Y1. In odd-numbered cell groups, the first word lines WLO may share sub-word line drivers SWD with an adjacent cell group in the row direction X1, and the second word lines WLE may share sub-word line drivers SWD with an adjacent cell group in a direction X2 opposite to the row direction X1. Conversely, in even-numbered cell groups, the second word lines WLE may share sub-word line drivers SWD with an adjacent cell group in the row direction X1, and the first word lines WLO may share sub-word line drivers SWD with an adjacent cell group in the direction X2.

For reference, a plurality of bit line sense amplifiers may be disposed between a plurality of cell blocks arranged in the column direction Y1. That is, two cell blocks adjacent to each other in the column direction Y1 may share the bit line sense amplifiers.

During one read or write operation, each cell block may input or output 8-bit data. During one read or write operation, one cell group may input or output 16-bit data, and 16-bit data output from one cell group may constitute one symbol. The ECC engine 150 may have the ability to correct an error occurring in one symbol. In the memory cell array of FIG. 2, the first to seventeenth cell groups MG0 to MG16 of the plurality of cell groups MG0 to MG18 may store the main data DATA′, and the eighteenth and nineteenth cell groups MG0 to MG16 may store the error correction code ECC. As a result, 17 symbols form 272-bit main data DATA′, and two symbols form 32-bit error correction code ECC, and during one read or write operation, a 304-bit codeword including the 272-bit main data DATA′ and the 32-bit error correction code ECC may be output.

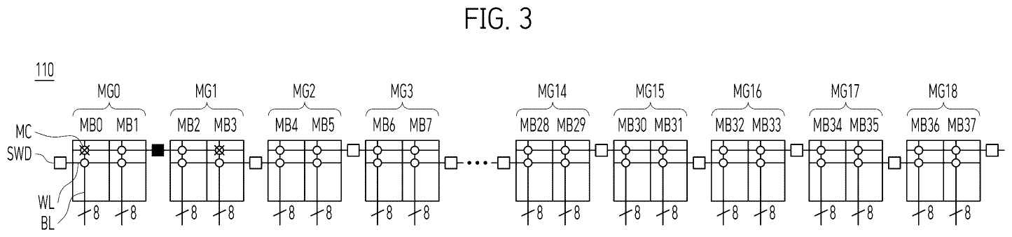

Since two cell groups adjacent to each other in the row direction X1 share the sub-word line drivers SWD, one sub-word line driver SWD may take charge of four cell blocks in the row direction X1. In this case, when a fault occurs in the shared sub-word line driver SWD, there is a tendency that a plurality of errors occur in cell blocks far from the sub-word line driver SWD. For example, when a fault occurs in a sub-word line driver shared by the first to fourth cell blocks MB0 to MB3, as illustrated in FIG. 3, when a fault occurs in a sub-word line driver shared by the first to fourth cell blocks MB0 to MB3, the probability of error occurring in the first cell block MB0 and the fourth cell block MB3 located at both ends is higher than the probability of error occurring in the second cell block MB1 and the third cell block MB2. In this case, when errors occur in the first cell block MB0 and the fourth cell block MB3, an error correction operation exceeds the error correction capability of the ECC engine 150 which performs the error correction operation in units of symbols, and thus an uncorrectable error UE occurs.

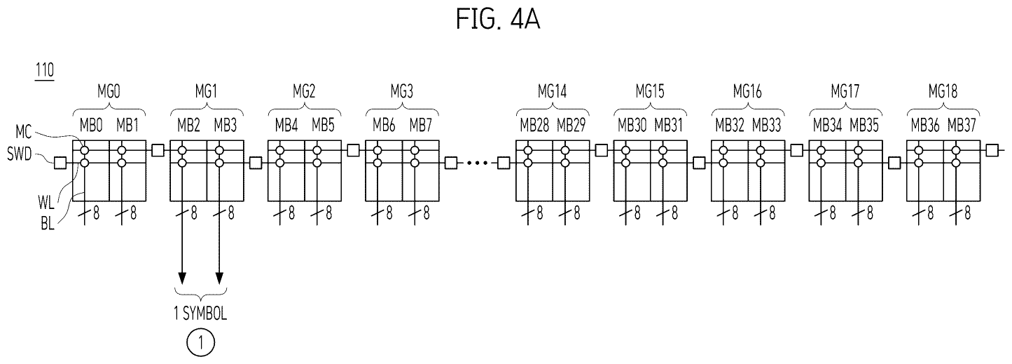

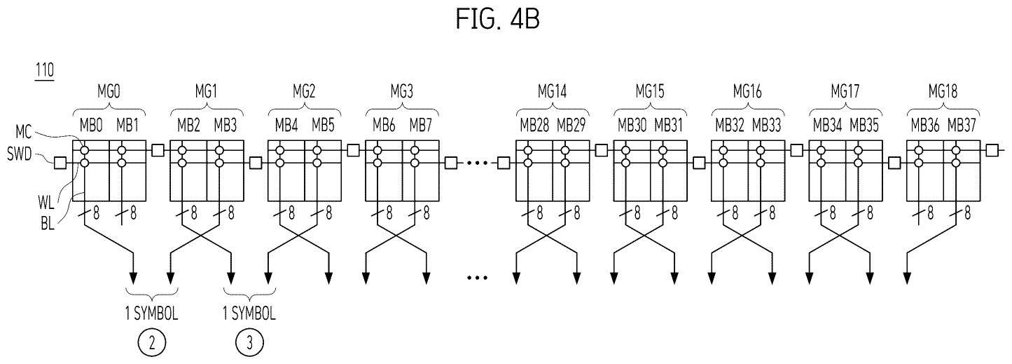

Hereinafter, in an embodiment of the present disclosure, data output from one cell group may be configured as one symbol, or data output from cell blocks disposed at both ends of two adjacent cell groups based on a shared sub-word line driver may be configured as one symbol. For example, as shown in FIG. 4A, 16-bit data output from the second cell group MG1 may be configured as one symbol (\textcircled{1}). Alternatively, as shown in FIG. 4B, data output from the first cell block MB0 and the fourth cell block MB3 disposed at both ends of two adjacent cell groups, i.e., the first cell group MG0 and the second cell group MG1, based on the sub-word line driver shared therebetween may be configured as one symbol (\textcircled{2}), or data output from the third cell block MB2 and the sixth cell block MB5 disposed at both ends of two adjacent cell groups, i.e., the second cell group MG1 and the third cell group MG2, based on the sub-word line driver shared therebetween may be configured as one symbol (\textcircled{3}). The ECC engine 150 may expand its error correction capability by performing an error correction operation in units of symbol (\textcircled{1}) of FIG. 4A or symbol (\textcircled{2} or \textcircled{3}) of FIG. 4B.

Hereinafter, in accordance with an embodiment of the present disclosure, a detailed configuration of the ECC engine 150 will be described. Before describing the configuration of the ECC engine 150, a check matrix used in an embodiment of the present disclosure will be described.

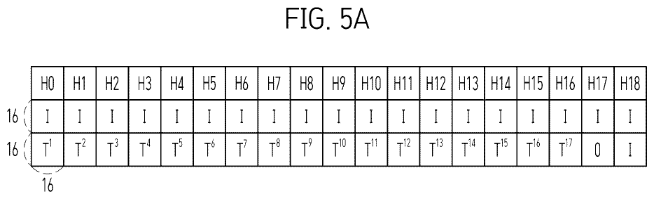

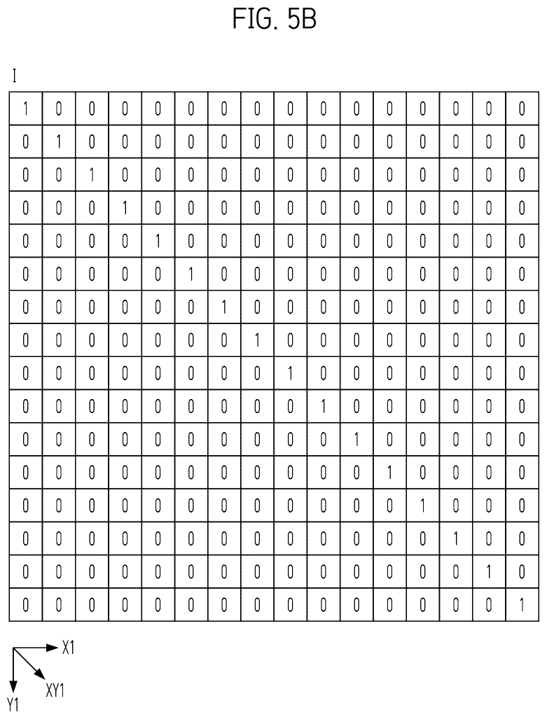

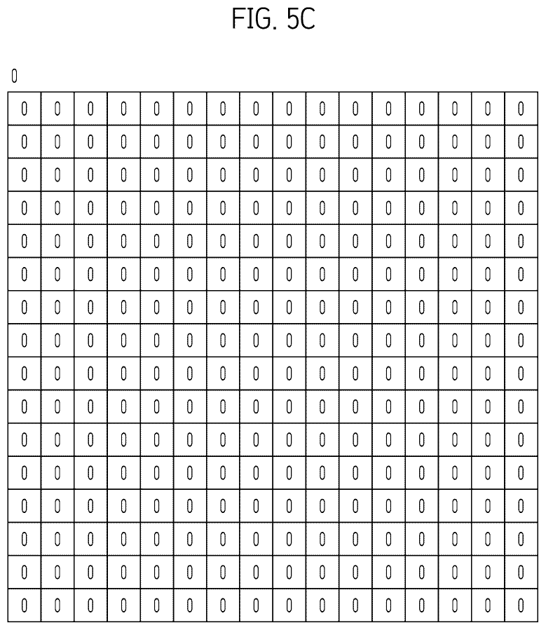

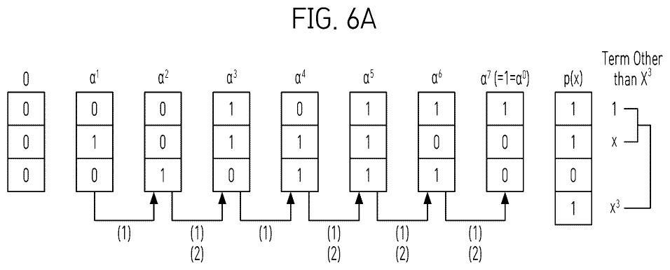

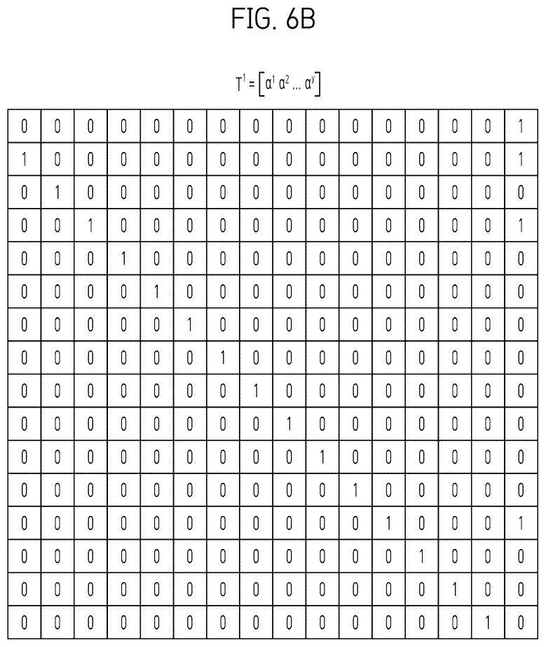

FIGS. 5A to 6B are diagrams for describing a configuration of a check matrix used by an ECC engine, according to an embodiment of the present disclosure.

Referring to FIG. 5A, the check matrix may include a matrix of (number of bits of error correction code)*(number of bits of data+number of bits of error correction code). Because the error correction code ECC is 32 bits and the data is 272 bits, the check matrix may include a matrix of 32*304. Each component of the check matrix may have a value of 1 or 0.

The check matrix may be composed of first to nineteenth H matrices H0 to H18 corresponding to each symbol. Each H matrix may be composed of a row corresponding to bits (i.e., 32 bits) of the error correction code ECC and a column corresponding to bits (i.e., 16 bits) of the corresponding symbol. Each H matrix may include an upper matrix composed of (symbol size)*(symbol size), that is, a square matrix of 16*16, and a lower matrix of the same size as the upper matrix. Each upper matrix of the first to nineteenth H matrices H0 to H18 may be composed of a unit matrix I of 16*16. Each lower matrix of the first to seventeenth H matrices H0 to H16 corresponding to the data DATA may be composed of a companion matrix of 16*16, such as T¹, T², T³, . . . T¹⁷. The lower matrix of the eighteenth H matrix H17 corresponding to lower bits of the error correction code ECC may be composed of a zero matrix 0 of 16*16, and the lower matrix of the nineteenth H matrix H18 corresponding to upper bits of the error correction code ECC may be composed of a unit matrix I of 16*16.

As illustrated in FIG. 5B, in the unit matrix I of 16*16, components of i*i, where i is an integer from 1 to 16, in a diagonal direction XY1, among 16 row components and 16 column components, may be set to a value of 1, and the remaining components may be set to a value of 0. As illustrated in FIG. 5C, in the zero matrix 0 of 16*16, all column components and row components may be set to a value of 0.

Before the configuration of the H matrix is described, a Galois field, a primitive element, a primitive polynomial and a companion matrix will be described.

The Galois field: A Galois field (GF) refers to a field with a finite number of elements, and a Galois field with a size X has a finite number of X elements from 0 to (X−1). For example, a Galois field with a finite number of 16 (=2⁴) elements from 0 to 15 may exist, and may be expressed as GF(16) or GF(2⁴).

The primitive element: All elements except 0 in the Galois field (GF) may be expressed as the square of some element α, and this element is called a primitive element. When a certain Galois field is expressed as GF(2ⁿ), 2 may be used as a primitive element. For example, elements of GF(2³) are as follows: GF(2³)={0, α¹, α², α³, α⁴, α⁵, α⁶, α⁷(=1=α⁰)}. The last element α⁷ of the Galois field is also expressed as 1 or α⁰.

The primitive polynomial: When a Galois field is generated, a primitive polynomial is used, which determines which of the square forms of α each element in the Galois field corresponds to. Even with Galois fields with the same size, a corresponding form may vary depending on a primitive polynomial that is selected.

When GF(2³) is generated using a primitive polynomial p(x)=x³+x+1 and α=2, a result illustrated in FIG. 6A may be obtained. The following rules such as (1) and (2) may be used to determine αⁱ.
(1) Because αⁱ is a value obtained by multiplying αⁱ⁻¹ by α (=2), αⁱ is shifted by 1 bit.
(2) When 1 is generated at a x³ location of p(x) due to the shift, an XOR operation is performed on the result of (1) and a term other than x³ in order to replace 1 with the term other than x³.

Referring to FIG. 6A, α² may be generated from α¹ by applying the rule (1). That is, α² may be (0, 0, 1) by shifting 1 bit from (0, 1, 0) of α¹.

α3 may be generated from α² by applying the rules (1) and (2). First, the rule of (1) may be applied so that (0, 0, 1) is changed to (0, 0, 0), and then the rule of (2) may be applied, that is, an XOR operation is performed on (0, 0, 0) and (1, 1, 0) to obtain (1, 1, 0).

α⁴ may be generated from α³ by applying the rule (1), that is, may be (0, 1, 1) by being shifted from (1, 1, 0).

α⁵ may be generated as (0, 0, 1) from α⁴ by applying the rule (1), and then the rule of (2) may be applied, that is, an XOR operation is performed on (0, 0, 1) and (1, 1, 0) to obtain (1, 1, 1).

α⁶ and α⁷ may also be generated by applying the same rules.

The companion matrix: The companion matrix may refer to a matrix including column vectors of α¹. For example, a companion matrix T^{j} having a size of y*y may be a matrix including column vectors of α^{j}, α^{j+1}, α^{j+2}, . . . , α^{j+y-1}. Likewise, a companion matrix T¹ may be a matrix including column vectors of α¹, α², α³, . . . α^{y}.

Referring to FIG. 6B, companion matrices each having a size of 16*16 generated by using elements of GF(α¹⁶) generated by a primitive polynomial p(x)=x¹⁶+x¹²+x³+x¹+1 and α=2.

The companion matrix T¹ may include a plurality of column vectors of α¹, α², α³, . . . , and α¹⁶. α¹ may have a column vector of (0, 1, 0, 0, 0, 0, 0, 0, 0, 0, 0, 0, 0, 0, 0, 0), and α² may have a column vector of (0, 0, 1, 0, 0, 0, 0, 0, 0, 0, 0, 0, 0, 0, 0, 0) shifted from α¹ by 1 bit. α³ may have a column vector (0, 0, 0, 1, 0, 0, 0, 0, 0, 0, 0, 0, 0, 0, 0, 0) shifted from α² by 1 bit. α¹⁵ may have a column vector of (0, 0, 0, 0, 0, 0, 0, 0, 0, 0, 0, 0, 0, 0, 0, 1), and α¹⁶ may have a column vector of (1, 1, 0, 1, 0, 0, 0, 0, 0, 0, 0, 0, 1, 0, 0, 0) generated by shifting from α¹⁵ by 1 bit and by using the primitive polynomial p(x)=x¹⁶+x¹²+x³+x¹+1.

In an embodiment of the present disclosure, a check matrix modified from the check matrix described in FIG. 5A may be used to perform an error correction operation in units of symbols of FIG. 4A or symbols of FIG. 4B.

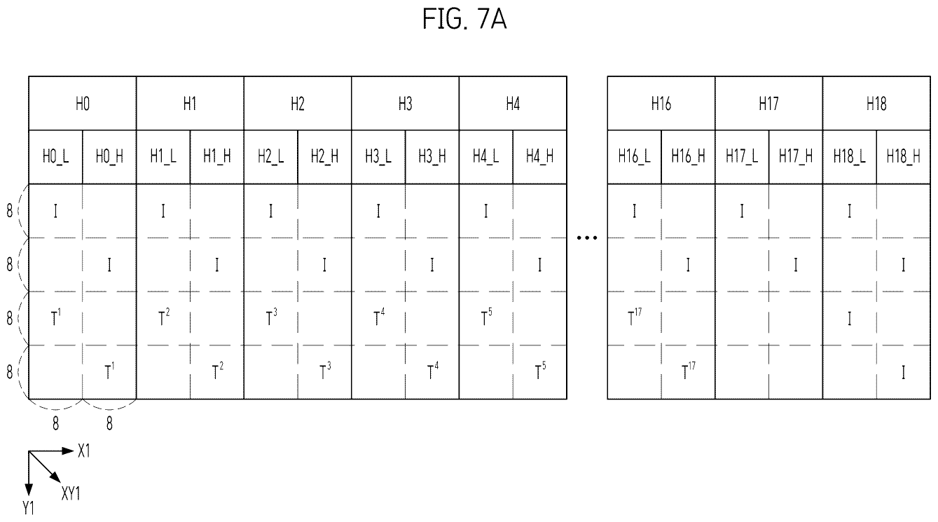

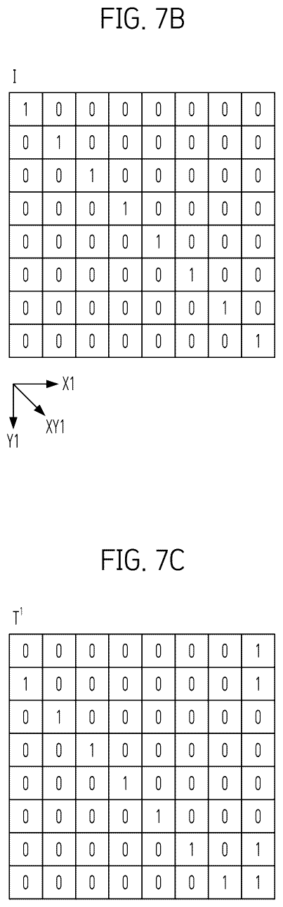

FIGS. 7A to 7C are diagrams for describing a configuration of a check matrix according to an embodiment of the present disclosure.

Referring to FIG. 7A, the check matrix may include a matrix of (number of bits of error correction code)*(number of bits of data+number of bits of error correction code). The check matrix may be composed of first to nineteenth H matrices H0 to H18 corresponding to each symbol. Each H matrix may be composed of a row corresponding to bits (i.e., 32 bits) of the error correction code ECC and a column corresponding to bits (i.e., 16 bits) of the corresponding symbol. Hereinafter, among the first to nineteenth H matrices H0 to H18, the first to seventeenth H matrices H0 to H16 corresponding to the first to seventeenth cell groups MG0 to MG16 storing the data DATA are referred to as data matrices, and the eighteenth and nineteenth matrices H17 and H18 corresponding to the eighteenth and nineteenth cell groups MG17 and MG18 storing the error correction code ECC are referred to as parity matrices.

Each of the data matrices H0 to H16 may include an upper portion in which two unit matrices I are arranged in a diagonal direction XY1 and a lower portion in which two identical companion matrices T^{k}, where k is an integer greater than or equal to 1, are arranged in the diagonal direction XY1. The diagonal direction XY1 may be a direction in which a row direction X1 and a column direction Y1 intersect. Each of the parity matrices H17 and H18 may include an upper portion in which two unit matrices I are arranged in the diagonal direction XY1 and a lower portion in which two unit matrices I are arranged in the diagonal direction XY1 or two zero matrices 0 are arranged in the diagonal direction XY1. For example, the parity matrix H17 may include an upper portion in which two unit matrices I are arranged in the diagonal direction XY1 and a lower portion in which two zero matrices 0 are arranged in the diagonal direction XY1, and the parity matrix H18 may include an upper portion and a lower portion in which two unit matrices I are arranged in the diagonal direction XY1.

Each H matrix may be divided into two sub-matrices. The first to nineteenth H matrices H0 to H18 may respectively correspond to the first to nineteenth cell groups MG0 to MG18, and first to 38-th sub-matrix H0_L to H18_H may respectively correspond to the first to 38-th cell blocks MB0 to MB37. Each sub-matrix may include an upper portion composed of two square matrices of (symbol size/2)*(symbol size/2), that is, 8*8, and a lower portion composed of two square matrices of the same size. That is, two unit matrices I may be arranged in the diagonal direction XY1 at an upper portion of two sub-matrices included in one data matrix, and two identical companion matrices T^{k} may be arranged in the diagonal direction XY1 at a lower portion of two sub-matrices included in one data matrix. In addition, two unit matrices I may be arranged in the diagonal direction XY1 at an upper portion of two sub-matrices included in one parity matrix, and two unit matrices I or two zero matrices 0 may be arranged in the diagonal direction XY1 at a lower portion of two sub-matrices included in one parity matrix.

Each of the unit matrix I, the zero matrix 0, and the companion matrix T^{k} may be composed of a square matrix having a size of 8*8.

As illustrated in FIG. 7B, in the unit matrix I of 8*8, components of j*j, where j is an integer from 1 to 8, in the diagonal direction XY1, among 8 row components and 8 column components, may be set to a value of 1, and the remaining components may be set to a value of 0. In the zero matrix 0, all column components and row components may be set to a value of 0.

Each of the companion matrices T^{k} may be configured by a matrix including a plurality of column vectors of α^{k} to α^{k+m-1}, where m is the number of bits of data output from one cell block. The companion matrix of 8*8 may be generated by using elements of GF (2⁸) generated by a primitive polynomial p(x)=x⁸+x⁷+x⁶+x¹+1, α=2. For example, as illustrated in FIG. 7C, the companion matrix T¹ may include a plurality of column vectors of α¹, α², α³, . . . , and α⁸. α¹ may have a column vector of (0, 1, 0, 0, 0, 0, 0, 0), and α² may have a column vector of (0, 0, 1, 0, 0, 0, 0, 0) shifted from α¹ by 1 bit. Also, α³ may have a column vector of (0, 0, 0, 1, 0, 0, 0, 0) shifted from α² by 1 bit. α⁷ may have a column vector of (0, 0, 0, 0, 0, 0, 0, 1), and α⁸ may have a column vector of (1, 1, 0, 0, 0, 0, 1, 1) generated by shifting from α⁷ by 1 bit and by using the primitive polynomial p(x)=x⁸+x⁷+x⁶+x¹+1. The k values of the companion matrices T^{k} may be set to have positive integers different from each data matrix. Although the k values of the companion matrices T^{k} increase by 1 in FIG. 7A, the embodiments are not limited thereto, and the k values of the companion matrices may be set to various values. Preferably, the k values of the companion matrices may be set to various values that do not overlap each other.

In an embodiment, the ECC generation circuit 152 may generate an error correction code ECC<0:31> by calculating data DATA<0:271> and a check matrix described in FIG. 7A during a write operation. The ECC generation circuit 152 may generate upper bits ECC<16:31> of the error correction code ECC<0:31> by performing a matrix-multiplication on a matrix of a vector expression of the data DATA<0:271> and a matrix of 272*16, which is the lower portion of the data matrices H0 to H16. Further, the ECC generation circuit 152 may generate a 16-bit code by performing a matrix-multiplication on the matrix of the vector expression of the data DATA<0:271> and a matrix of 272*16, which is the upper portion of the data matrices H0 to H16, and generate lower bits ECC<0:15> of the error correction code ECC<0:31> by performing a logic XOR operation on the 16-bit code and the upper bits ECC<16:31> of the error correction code ECC<0:31>. As a result, the data DATA<0:271> may be stored in the first to seventeenth cell groups MG0 to MG16, the lower bits ECC<0:15> of the error correction code ECC<0:31> may be stored in the eighteenth cell group MG17, and the 2 upper bits ECC<16:31> of the error correction code ECC<0:31> may be stored in the nineteenth cell group MG18.

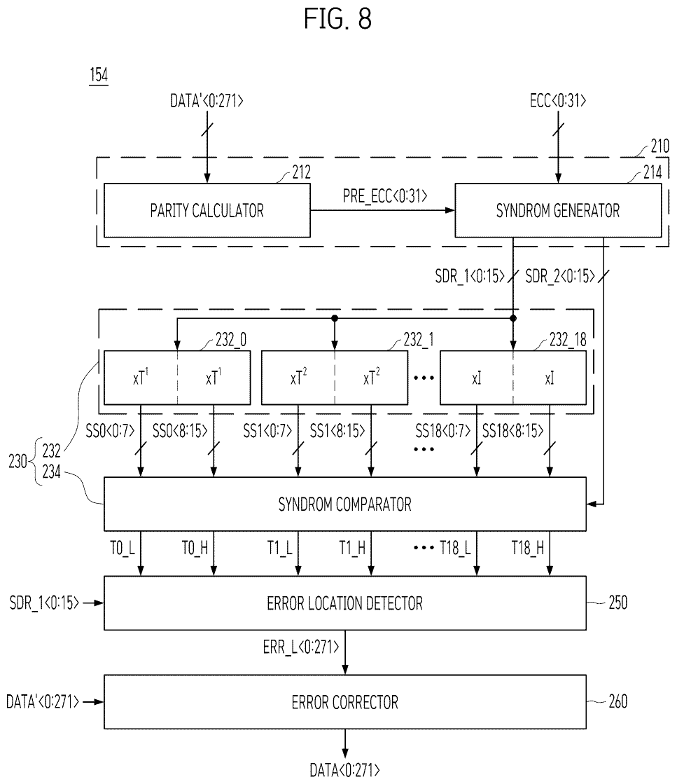

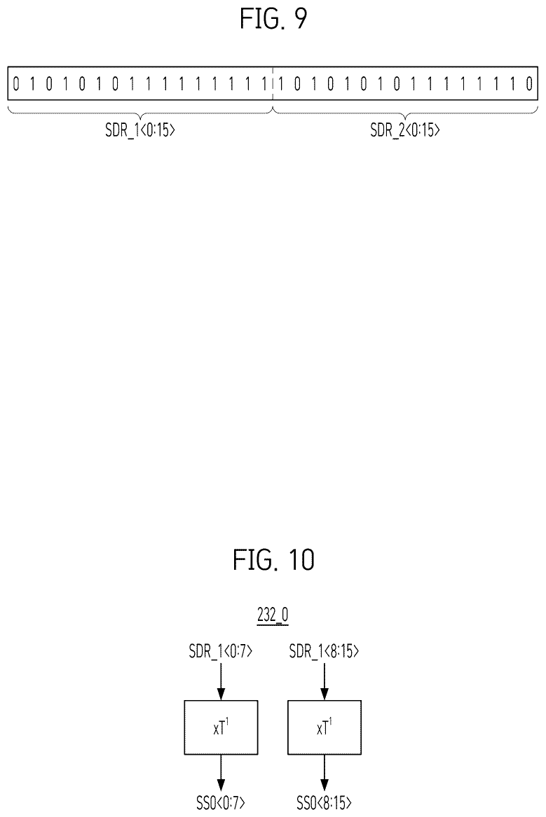

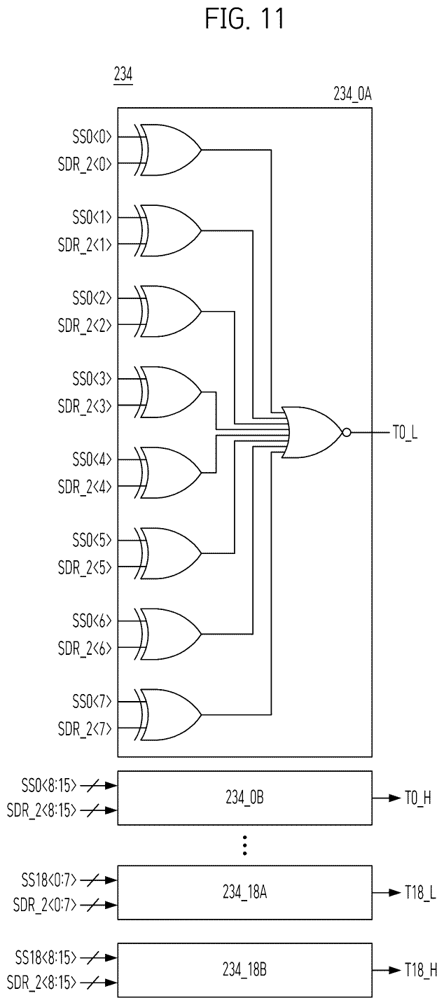

FIG. 8 is a block diagram illustrating the error correction circuit 154 according to an embodiment of the present disclosure. FIG. 9 is a diagram for describing a first syndrome SDR_1<0:15> and a second syndrome SDR_2<0:15> generated in a syndrome generation circuit 210 of FIG. 8, according to an embodiment of the present disclosure. FIG. 10 is a detailed block diagram illustrating a first multiplier 232_0 of FIG. 8, according to an embodiment of the present disclosure. FIG. 11 is a detailed circuit diagram illustrating a syndrome comparator 234 of FIG. 8, according to an embodiment of the present disclosure.

Referring to FIG. 8, the error correction circuit 154 may include a syndrome generation circuit 210, a syndrome comparison circuit 230, an error location detector 250, and an error corrector 260.

The syndrome generation circuit 210 may generate a first syndrome SDR_1<0:15> and a second syndrome SDR_2<0:15> by calculating a check matrix with the main data DATA′<0:271> and the error correction code ECC<0:31> output from the memory core 110.

In detail, the syndrome generation circuit 210 may include a parity calculator 212 and a syndrome generator 214.

The parity calculator 212 may generate a 32-bit preliminary error correction code PRE_ECC<0:31> by calculating a check matrix with the 272-bit main data DATA′<0:271> output from the first to seventeenth cell groups MG0 to MG16 of the memory core 110. The parity calculator 212 may use the data matrices H0 to H16 described in FIG. 7A. That is, the parity calculator 212 may generate the 32-bit preliminary error correction code PRE_ECC<0:31> by performing a matrix-multiplication on a matrix of a vector expression of the main data DATA′<0:271> and the data matrix H0 to H16 of 272*32.

The syndrome generator 214 may generate the first syndrome SDR_1<0:15> and the second syndrome SDR_2<0:15> by comparing the 32-bit error correction code ECC<0:31> output from the eighteenth and nineteenth cell groups MG17 and MG18, with the 32-bit preliminary error correction code PRE_ECC<0:31> generated by the parity calculator 212. The syndrome generator 214 may generate the 16-bit first syndrome SDR_1<0:15> by performing a logic XOR operation on the lower 16 bits ECC<0:15> of the error correction code ECC<0:31> and lower 16 bits PRE_ECC<0:15> of the preliminary error correction code PRE_ECC<0:31>, respectively. The syndrome generator 214 may generate the 16-bit second syndrome SDR_2<0:15> by performing a logic XOR operation on the upper 16 bits ECC<16:31> of the error correction code ECC<0:31> and upper 16 bits PRE_ECC<16:31> of the preliminary error correction code PRE_ECC<0:31>, respectively. The first syndrome SDR_1<0:15> may be used to indicate an error pattern within a symbol, and the second syndrome SDR_2<0:15> may be used to indicate a location of a symbol containing an error. For example, referring to FIG. 9, the first syndrome SDR_1<0:15> of “01010101 11111111” may mean an error pattern with two error bits in a symbol, and the second syndrome SDR_2<0:15> of “10101010 11111110” may indicate that a symbol containing an error is output from the first cell group MG1.

The syndrome comparison circuit 230 may calculate the first syndrome SDR_1<0:15> and a check matrix to generate first to nineteenth sub-syndromes SS0<0:15> to SS18<0:15> corresponding to the first to nineteenth cell groups MG0 to MG18, respectively. The syndrome comparison circuit 230 may compare the first to nineteenth sub-syndromes SS0<0:15> to SS18<0:15> and the second syndrome SDR_2<0:15>, respectively, to generate first to 38-th syndrome comparison signals T0_L, T0_H, T1_L, T1_H, . . . T18_L and T18_H. In this case, since each H matrix of the check matrix is divided into two sub-matrixes, the syndrome comparison circuit 230 may be configured to generate the first to 38-th syndrome comparison signals T0_L to 18_H, corresponding to the first to 38-h cell blocks MB0 to MB37, respectively.

In detail, the syndrome comparison circuit 230 may include a syndrome multiplier 232 and a syndrome comparator 234.

The syndrome multiplier 232 may generate first to nineteenth sub-syndromes SS0<0:15> to SS18<0:15> by performing a matrix-multiplication on the first syndrome SDR_1<0:15> and a lower portion of the check matrix. In this case, as described in FIG. 7A, two identical companion matrices T^{k} may be disposed in the diagonal direction XY1 at the lower portion of the data matrices H0 to H16, and two unit matrices I or two zero matrices 0 may be disposed in the diagonal direction XY1 at the lower portion of the parity matrices H17 and H18.

The syndrome multiplier 232 may include first to nineteenth multipliers 232_0 to 232_18 corresponding to the first to nineteenth H matrices H0 to H18, each of which generates a corresponding sub-syndrome by performing a matrix-multiplication on the first syndrome SDR_1<0:15> and a lower portion of a corresponding H matrix. The first to nineteenth sub-syndromes SS0<0:15> to SS18<0:15> may be divided into a lower sub-syndrome SS #<0:7>, where # is an integer from 0 to 18, and an upper sub-syndrome SS #<8:15>.

The first to seventeenth multipliers 232_0 to 232_16 may generate first to seventeenth lower sub-syndromes SS0<0:7> to SS16<0:7> by performing a matrix-multiplication on lower 8 bits SDR_1<0:7> of the first syndrome SDR_1<0:15> and a companion matrices T^{k} of 8*8, and generate first to seventeenth upper sub-syndromes SS0<8:15> to SS16<8:15> by performing a matrix-multiplication on upper 8 bits SDR_1<8:15> of the first syndrome SDR_1<0:15> and a companion matrices T^{k} of 8*8. For example, referring to FIG. 10, the first multiplier 232_0 may generate the first lower sub-syndrome SS0<0:7> by performing a matrix-multiplication on the lower 8 bits SDR_1<0:7> and the companion matrix T¹ of 8*8, and may generate the first upper sub-syndrome SS0<8:15> by performing a matrix-multiplication on the upper 8 bits SDR_1<8:15> and the companion matrix T¹ of 8*8. The first to seventeenth multipliers 232_0 to 232_16 may be referred to as data multipliers.

The eighteenth multiplier 232_17 may generate the eighteenth lower sub-syndrome SS17<0:7> by performing a matrix-multiplication on the lower 8 bits SDR_1<0:7> of the first syndrome SDR_1<0:15> and a zero matrix 0 of 8*8, and may generate the eighteenth upper sub-syndrome SS17<8:15> by performing a matrix-multiplication on the upper 8 bits SDR_1<8:15> of the first syndrome SDR_1<0:15> and a zero matrix 0 of 8*8. As a result, the eighteenth sub-syndrome SS17<0:15> may be composed of all-zero bits. In addition, the nineteenth multiplier 232_18 may generate the nineteenth lower sub-syndrome SS18<0:7> by performing a matrix-multiplication on the lower 8 bits SDR_1<0:7> of the first syndrome SDR_1<0:15> and a unit matrix I of 8*8, and may generate the nineteenth upper sub-syndrome SS18<8:15> by performing a matrix-multiplication on the upper 8 bits SDR_1<8:15> of the first syndrome SDR_1<0:15> and a unit matrix I of 8*8. As a result, the nineteenth sub-syndrome SS18<0:15> may be composed of bits same as the first syndrome SDR_1<0:15>. The eighteenth multiplier 232_17 and the nineteenth multiplier 232_18 may be referred to as parity multipliers.

The syndrome comparator 234 may generate the first to 38-th syndrome comparison signals T0_L to T18_H by comparing the lower sub-syndrome SS #<0:7> and the upper sub-syndrome SS #<8:15>, which are included in the first to nineteenth sub-syndromes SS0<0:15> to SS18<0:15>, with the lower 8 bits SDR_2<0:7> and the upper 8 bits SDR_2<8:15> of the second syndrome SDR_2<8:15>, respectively.

Referring to FIG. 11, the syndrome comparator 234 may include first to 38-th comparators 234_0A to 234_18B. Each comparator may output a corresponding syndrome comparison signal by comparing a corresponding lower sub-syndrome SS #<0:7> and the lower 8 bits SDR_2<0:7> of the second syndrome SDR_2<0:15> by bit, or compare a corresponding upper sub-syndrome SS #<8:15> and the upper 8 bits SDR_2<8:15> of the second syndrome SDR_2<0:15> by bit. For example, the first comparator 234_0A may compare the first lower sub-syndrome SS0<0:7> and the lower 8 bits SDR_2<0:7> of the second syndrome SDR_2<0:15> to output the first syndrome comparison signal T0_L. The first comparator 234_0A may output the first syndrome comparison signal T0_L at a logic high level when the first lower sub-syndrome SS0<0:7> is identical to the lower 8 bits SDR_2<0:7>. On the other hand, the first comparator 234_0A may output the first syndrome comparison signal T0_L at a logic low level when any bit of the first lower sub-syndrome SS0<0:7> is different from the lower 8 bits SDR_2<0:7>. Each of the comparators 234_0A to 234_18B may be implemented with logic XOR gates and NOR gates.

With the above configuration, when a correctable error is included in a symbol in which an error has occurred, since the sub-syndromes corresponding to the symbol are identical to the second syndrome SDR_2<0:15>, the syndrome comparison circuit 230 may output a corresponding syndrome comparison signal at a logic high level. On the other hand, since the sub-syndromes corresponding to the symbols in which no error has occurred are not identical to the second syndrome SDR_2<0:15>, the syndrome comparison circuit 230 may output a corresponding syndrome comparison signal at a logic low level. Furthermore, when an uncorrectable error exceeding the error correction capability of the error correction circuit 154 is included, the sub-syndromes of all symbols are not the identical to the second syndrome SDR_2<0:15>, and thus the syndrome comparison circuit 230 may output all syndrome comparison signals at a logic low level.

The error location detector 250 may generate an error location signal ERR_L<0:271> based on the first to 38-th syndrome comparison signals T0_L to T18_H. The error location detector 250 may determine an error location in units of symbols based on the first to 38-th syndrome comparison signals T0_L to T18_H, and generate the error location signal ERR_L<0:271> by reflecting the determined error location onto the first syndrome SDR_1<0:15>. The error location signal ERR_L<0:271> includes bits corresponding to the bits of the main data DATA′<0:271>, and a bit corresponding to an error bit among the bits of the main data DATA′<0:271> may be set to a high bit. In an embodiment, a symbol unit may include data (\textcircled{1}) output from one cell group as described in FIG. 4A, or data (\textcircled{2} or \textcircled{3}) output from cell blocks disposed at both ends of two adjacent cell groups based on a sub-word line driver shared therebetween, as described in FIG. 4B.

The error corrector 260 may generate error-corrected data DATA<0:271> by correcting an error in the main data DATA′<0:271> according to the error location signal ERR_L<0:271>. The error corrector 260 may perform an error correction operation by inverting an error bit of the main data DATA′<0:271> according to a high bit among bits of the error location signal ERR_L<0:271>. For example, the error corrector 260 may include logic gates for performing a logic XOR operation on each bit of the error location signal ERR_L<0:271> and the main data DATA′<0:271>.

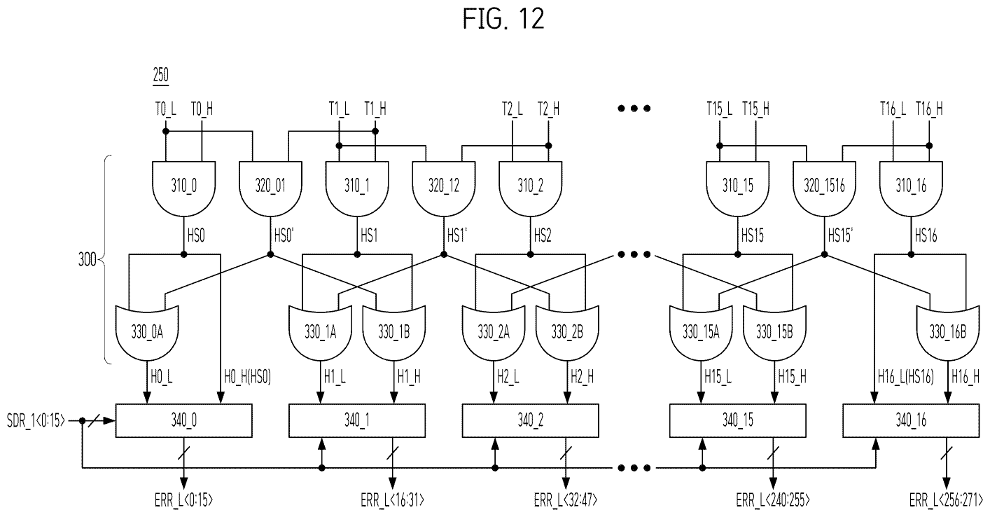

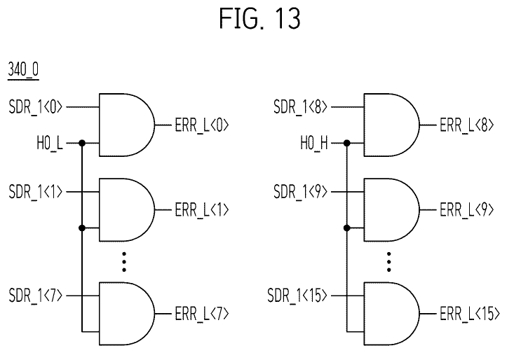

FIG. 12 is a detailed circuit diagram illustrating the error location detector 250 of FIG. 8, according to an embodiment of the present disclosure. FIG. 13 is a detailed circuit diagram illustrating an error detector 340_0 of FIG. 12, according to an embodiment of the present disclosure.

Referring to FIG. 12, the error location detector 250 may include a symbol adder 300 and a plurality of error detectors 340_0 to 340_16.

The symbol adder 300 may generate first to seventeenth operational signals HS0 to HS16 based on syndrome comparison signals corresponding to cell blocks included in one cell group, among the syndrome comparison signals T0_L to T18_H, and generate first to sixteenth adjacent operational signals HS0′ to HS15′ based on syndrome comparison signals corresponding to cell blocks disposed at both ends of two adjacent cell groups. The symbol adder 300 may generate first to 34-th preliminary detection signals H0_L to H16_H by summing the first to seventeenth operational signals HS0 to HS16 and the first to sixteenth adjacent operational signals HS0′ to HS15′.

In detail, the symbol adder 300 may include a plurality of first logic AND gates 310_0 to 310_16, a plurality of second logic AND gates 320_01 to 320_1516, and a plurality of logic OR gates 330_0A to 330_16B. The plurality of first logic AND gates 310_0 to 310_16 and the plurality of error detectors 340_0 to 340_16 may be provided for as many (i.e., 17) corresponding to the number of the plurality of cell groups for storing data, respectively, and the plurality of second logic AND gates 320_01 to 320_1516 may be provided for as many (i.e., 16) corresponding to the number of adjacent cell groups among the plurality of cell groups for storing data.

The plurality of first logic AND gates 310_0 to 310_16 may output the first to seventeenth operational signals HS0 to HS16 by performing a logic AND operation on syndrome comparison signals corresponding to two cell blocks included in each cell group. For example, the first logic AND gate 310_0 may output the first operational signal HS0 by performing a logic AND operation on the first and second syndrome comparison signals T0_L and T0_H corresponding to the first cell group MG0. The first logic AND gate 310_1 may output the second operational signal HS1 by performing a logic AND operation on the third and fourth syndrome comparison signals T1_L and T1_H corresponding to the second cell group MG1. In this way, the first logic AND gate 310_16 may output the seventeenth operational signal HS16 by performing a logic AND operation on the 33-th and 34-th syndrome comparison signals T16_L and T16_H corresponding to the seventeenth cell group MG16.

The plurality of second logic AND gates 320_01 to 320_1516 may output the first to sixteenth adjacent operational signals HS0′ to HS15′ by performing a logic AND operation on syndrome comparison signals corresponding to two cell blocks disposed at both ends of two adjacent cell groups based on the shared sub-word line driver. For example, the second logic AND gate 320_01 may output the second adjacent operational signal HS0′ by performing a logic AND operation on the first and fourth syndrome comparison signals T0_L and T1_H corresponding to the cell blocks MB0 and MB3 disposed at both ends of the first and second cell groups MG0 and MG1 based on the shared sub-word line driver. The second logic AND gate 320_12 may output the second adjacent operational signal HS1′ by performing a logic AND operation on the third and sixth syndrome comparison signals T1_L and T2_H corresponding to the cell blocks MB2 and MB5 disposed at both ends of the second and third cell groups MG1 and MG2 based on the shared sub-word line driver. In this way, the second logic AND gate 320_1516 may output the sixteenth adjacent operational signal HS15′ by performing a logic AND operation on the 31-th and 34-th syndrome comparison signals T15_L and T16_H corresponding to the cell blocks MB30 and MB33 disposed at both ends of the sixteenth and seventeenth cell groups MG15 and MG16 based on the shared sub-word line driver.

The plurality of logic OR gates 330_0A to 330_16B may generate the first to 34-th preliminary detection signals H0_L to H16_H by performing a logic OR operation on corresponding signals among the first to seventeenth operational signals HS0 to HS16 and the first to sixteenth adjacent operational signals HS0′ to HS15′, respectively. For example, the logic OR gate 330_0A may generate the first preliminary detection signal H0_L by performing a logic OR operation on the first operational signal HS0 and the first adjacent operational signal HS0′. The first operational signal HS0 may be output as the second preliminary detection signal H0_H. The logic OR gate 330_1A may generate the third preliminary detection signal H1_L by performing a logic OR operation on the second operational signal HS1 and the second adjacent operational signal HS1′, and the logic OR gate 330_1B may generate the fourth preliminary detection signal H1_H by performing a logic OR operation on the second operational signal HS1 and the first adjacent operational signal HS0′. In this way, the logic OR gate 330_16B may generate the 34-th preliminary detection signal H16_H by performing a logic OR operation on the seventeenth operational signal HS16 and the sixteenth adjacent operational signal HS15′. The seventeenth operational signal HS16 may be output as the 33-th preliminary detection signal H16_L.

The plurality of error detectors 340_0 to 340_16 may generate the error location signal ERR_L<0:271> by reflecting the first syndrome SDR_1<0:15> onto the first to 34th preliminary detection signals H0_L to H16_H. The plurality of error detectors 340_0 to 340_16 may perform a logic AND operation on the first to 34-th preliminary detection signals H0_L to H16_H and one of the lower bits SDR_1<0:7> and the upper bits SDR_1<8:15> of the first syndrome SDR_1<0:15>. For example, referring to FIG. 13, the error detector 340_0 may perform a logic AND operation on the first preliminary detection signal H0_L and the lower 8 bits SDR_1<0:7> to output the bits ERR_L<0:7> of the error location signal ERR_L<0:271>, and may perform a logic AND operation on the second preliminary detection signal H0_H and the upper 8 bits SDR_1<8:15> to output the bits ERR_L<8:15> of the error location signal ERR_L<0:271>. With the above configuration, the error detectors 340_0 to 340_16 may generate the error location signal ERR_L<0:271> by reflecting error pattern information included in the first syndrome SDR_1<0:15> onto the first to 34-th preliminary detection signals H0_L to H16_H.

In FIG. 12, a case where the error location detector 250 generates only the error location signal ERR_L<0:271> for correcting an error in the main data DATA′<0:271> is illustrated, but the error location detector 250 may also generate an error location signal for correcting an error in the error correction code ECC<0:31>. For example, the error location detector 250 may determine an error location in units of symbols based on the 35-th to 38-th syndrome comparison signals T17_L, T17_H, T18_L, and T18_H, among the first to 38-th syndrome comparison signals T0_L to T18_H, and generate an error location signal for correcting an error in the error correction code ECC<0:31> by reflecting the determined error location onto the first syndrome SDR_1<0:15>.

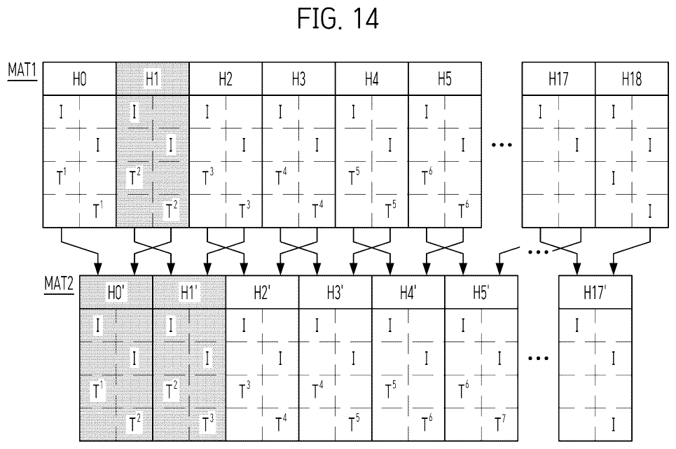

FIG. 14 is a table for describing a configuration of a check matrix according to an operation of the error location detector 250 of FIG. 12, according to an embodiment of the present disclosure.

Referring to FIG. 14, a check matrix MAT1 illustrated in an upper part may include first to nineteenth H matrices H0 to H18. The first to seventeenth H matrices H0 to H16 may correspond to the first to seventeenth operational signals HS0 to HS16 generated by performing a logic AND operation on syndrome comparison signals corresponding to two cell blocks included in a cell group, respectively.

A check matrix MAT2 illustrated in a lower part may include first to eighteenth H matrices H0′ to H17′. The first to eighteenth H matrices H0′ to H17′ may correspond to the first to sixteenth adjacent operational signals HS0′ to HS15′ generated by logic AND operation on syndrome comparison signals corresponding to two cell blocks disposed at both ends of two adjacent cell groups based on a shared sub-word line driver, respectively.

The error location detector 250 may generate the first to 34-th preliminary detection signals H0_L to H16_H by performing a logic OR operation on the first to seventeenth operational signals HS0 to HS16 and the first to sixteenth adjacent operational signals HS0′ to HS15′. Accordingly, the first to 34-th preliminary detection signals H0_L to H16_H may be output as a result of determining the error location in units of symbols according to an embodiment of the present disclosure.

As described above, in an embodiment of the present disclosure, in a memory device that corrects an error in read data in units of symbols, not only an error occurring in one symbol but also an error occurring at both ends of two adjacent symbols shared by a sub-word line driver may be corrected. Therefore, it is possible to expand the error correction capability of the memory device.

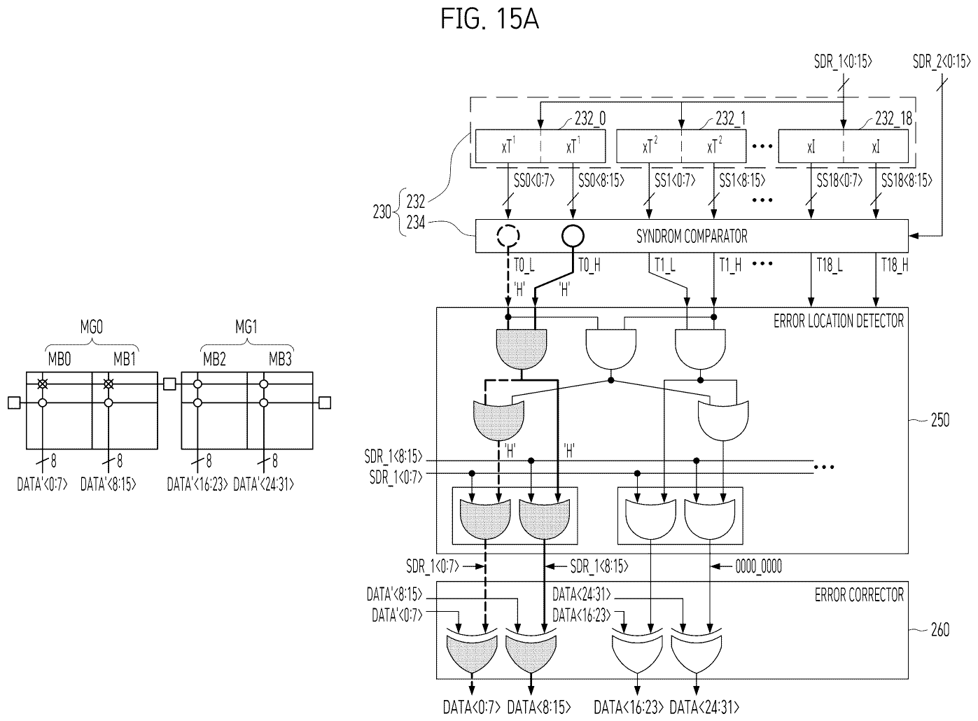

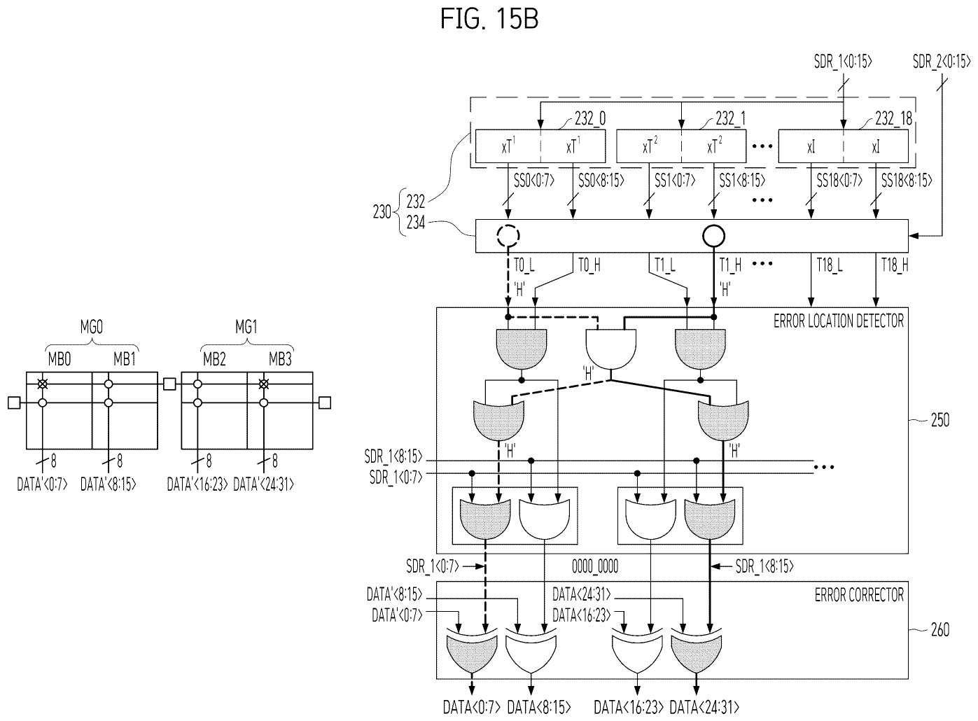

FIGS. 15A and 15B are diagrams illustrating an error correction operation according to an embodiment of the present disclosure.

Referring to FIG. 15A, a case where an error has occurred in two cell blocks MB0 and MB1 included in the first cell group MG0 is illustrated.

The syndrome generation circuit 210 may generate the first syndrome SDR_1<0:15> indicating an error pattern within a symbol and the second syndrome SDR_2<0:15> indicating a location of a symbol containing an error.

The syndrome comparison circuit 230 may output the first syndrome comparison signal T0_L and the second syndrome comparison signal T0_H at a logic high level since the first sub-syndrome SS0<0:15> corresponding to a symbol output from the first cell group MG0 is the same as the second syndrome SDR_2<0:15>. On the other hand, the syndrome comparison circuit 230 may output the remaining syndrome comparison signals T1_L to T18_H at a logic low level since the remaining sub-syndromes SS1<0:15> to SS18<0:15> are different from the second syndrome SDR_2<0:15>.

The symbol adder 300 may generate the first operational signal HS0 at a logic high level based on the first syndrome comparison signal T0_L and the second syndrome comparison signal T0_H, to thereby generate the first preliminary detection signal H0_L and the second preliminary detection signal H0_H at a logic high level. The error detector 340_0 may output the first syndrome SDR_1<0:15> as corresponding bits ERR_L<0:15> of the error location signal ERR_L<0:271>, according to the first preliminary detection signal H0_L and the second preliminary detection signal H0_H at a logic high level. In this case, the remaining bits ERR_L<16:271> are output at a logic low level.

The error corrector 260 may generate the error-corrected data DATA<0:271> by performing a logic XOR operation on each bit of the error location signal ERR_L<0:271> and the main data DATA'<0:271>. That is, the error corrector 260 may perform an error correction operation by inverting corresponding bits of the main data DATA′<0:271> according to the corresponding bits ERR_L<0:15> of the error location signal ERR_L<0:271>.

As described above, the error correction circuit 154 may correct the error of the main data DATA′<0:271> by configuring data output from one cell group (see FIG. 4A) in one symbol unit.

When an error occurs only in the first cell block MB0 included in the first cell group MG0, the upper 8 bits SDR_1<8:15> of the first syndrome SDR_1<0:15> and the upper 8 bits SDR_2<8:15> of the second syndrome SDR_2<0:15>, which are corresponding to the second cell block MB1 in which no error has occurred, may have all-zero values. Accordingly, only the error of the data DATA′<0:7> output from the first cell block MB0 may be corrected.

Referring to FIG. 15B, a case where an error has occurred in the first cell block MB0 included in the first cell group MG0 and the fourth cell block MB3 included in the second cell group MG1, respectively.

The syndrome generation circuit 210 may generate first syndrome SDR_1<0:15> indicating an error pattern within a symbol and the second syndrome SDR_2<0:15> indicating a location of a symbol containing an error.

The syndrome comparison circuit 230 may output the first syndrome comparison signal T0_L at a logic high level since the first lower sub-syndrome SS0<0:7> corresponding to a symbol output from the first cell block MB0 is the same as the second syndrome SDR_2<0:15>. The syndrome comparison circuit 230 may output the fourth syndrome comparison signal T1_H at a logic high level since the second upper sub-syndrome SS1<8:15> corresponding to a symbol output from the fourth cell block MB3 is the same as the second syndrome SDR_2<0:15>. On the other hand, the syndrome comparison circuit 230 may output the remaining syndrome comparison signals T0_H, T1_L, and T2_L to T18_H at a logic low level since the remaining sub-syndromes are different from the second syndrome SDR_2<0:15>.

The symbol adder 300 may generate the first adjacent operational signal HS0′ at a logic high level based on the first syndrome comparison signal T0_L and the fourth syndrome comparison signal T1_H, to thereby generate the first preliminary detection signal H0_L and the fourth preliminary detection signal H1_H at a logic high level. The error detector 340_0 may output lower 8 bits SDR_1<0:7> of the first syndrome SDR_1<0:15> as corresponding bits ERR_L<0:7> of the error location signal ERR_L<0:271>, according to the first preliminary detection signal H0_L at a logic high level. The error detector 340_1 may output upper 8 bits SDR_1<8:15> of the first syndrome SDR_1<0:15> as corresponding bits ERR_L<24:31> of the error location signal ERR_L<0:271>, according to the fourth preliminary detection signal H1_H at a logic high level. In this case, the remaining bits ERR_L<8:23, 32:271> are output at a logic low level.

The error corrector 260 may generate the error-corrected data DATA<0:271> by performing a logic XOR operation on each bit of the error location signal ERR_L<0:271> and the main data DATA′<0:271>. That is, the error corrector 260 may perform an error correction operation by inverting corresponding bits of the main data DATA′<0:271> according to the corresponding bits ERR_L<0:7, 24:35> of the error location signal ERR_L<0:271>.

As described above, the error correction circuit 154 may correct the error of the main data DATA′<0:271> by configuring data cell blocks arranged at both ends of two adjacent cell groups based on a shared sub-word line driver (see FIG. 4B), in one symbol unit.

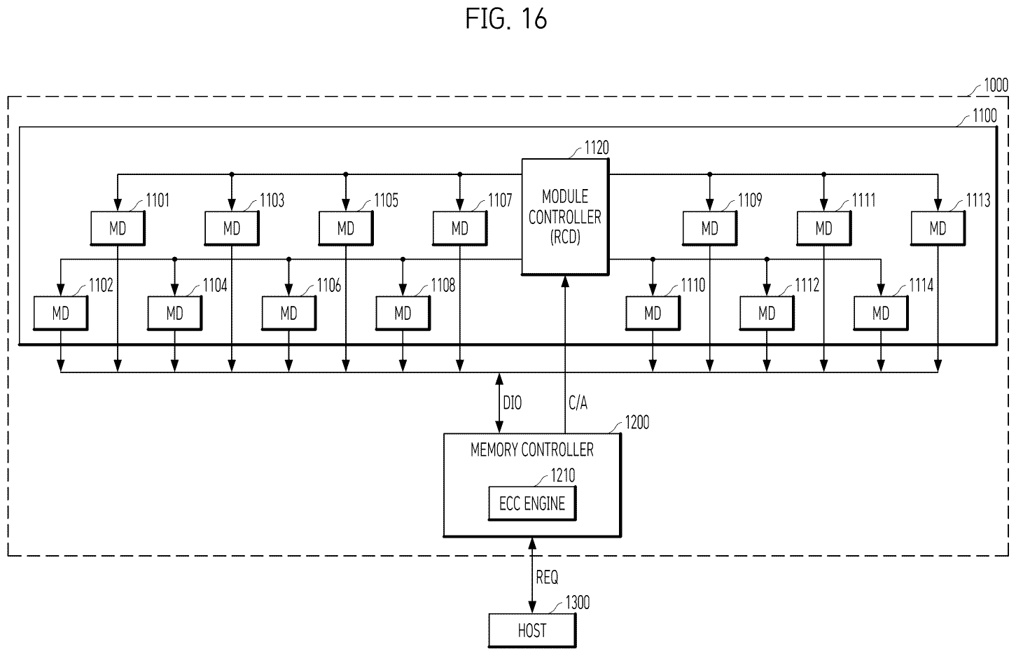

FIG. 16 is a block diagram illustrating a memory system 1000 including a memory module 1100 according to an embodiment of the present disclosure.

Referring to FIG. 16, the memory system 1000 may include the memory module 1100 and a memory controller 1200.

The memory controller 1200 may control operations of the memory system 1000 and control a data transfer between a host 1300 and the memory module 1100. The memory controller 1200 may generate a command/address signal C/A according to a request REQ from the host 1300 to provide the command/address signal C/A to the memory module 1100, and provide data DIO corresponding to the request REQ from the host 1300 to the memory module 1100, and provide data DIO read from the memory module 1100 to the host 1300.

The memory controller 1200 may include an error correction code (ECC) engine 1210. The ECC engine 1210 may detect and correct an error in the data DIO read from the memory device 100 and provide error-corrected data to the host 1300. When the number of error bits of the data DIO exceeds an error correction capability of the ECC engine 1210, the memory controller 1200 may notify the host 1300 that an uncorrectable error (UE) has occurred.

The memory module 1100 may include a plurality of memory devices (MD) 1101 to 1114 and a module controller (RCD) 1120. The module controller 1120 may include a known register clock driver. The module controller 1120 may control the memory devices 1101 to 1114 under the control of the memory controller 1200. For example, the module controller 1120 may receive the command/address signal C/A from the memory controller 1200 and control the data DIO to be written to the memory devices 1101 to 1114 or read from the memory devices 1101 to 1114.

Each of the memory devices 1101 to 1114 may correspond to the memory device 100 described in FIG. 1. That is, each of the memory devices 1101 to 1114 may include a memory core and an ECC engine. The ECC engine may correct not only an error occurring in one symbol but also an error occurring at both ends of two adjacent symbols. Therefore, it is possible to expand an error correction capability of the memory device.

Depending on an embodiment, some (e.g., 1101 to 1112) of each of the memory devices 1101 to 1114 may store main data DATA', and the remaining devices (e.g., 1113 and 1114) may store an error correction code ECC. In this case, the ECC engine 1210 of the memory controller 1200 may correspond to the ECC engine 150 of FIG. 1. That is, the ECC engine 1210 may correct not only an error occurring in one symbol but also an error occurring at both ends of two adjacent symbols. Depending on an embodiment, the module controller 1120 may include an ECC engine corresponding to the ECC engine 150 of FIG. 1.

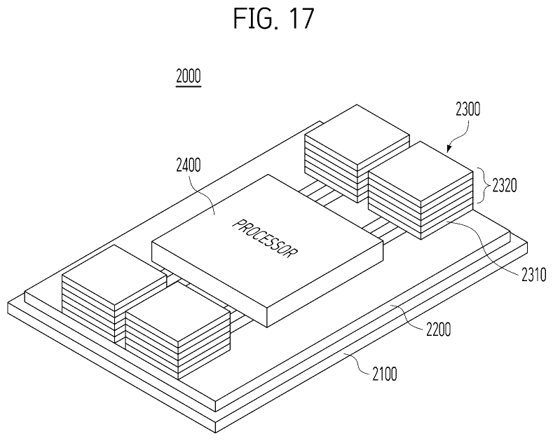

FIG. 17 is a block diagram illustrating a memory system 2000 including a stacked memory device 2300 according to an embodiment of the present disclosure.

Referring to FIG. 17, the memory system 2000 may include a package substrate 2100, an interposer 2200, stacked memory devices 2300, and a processor 2400.

The package substrate 2100 may include a printed circuit board (PCB). The package substrate 2100 may be electrically connected to an external system board, main board, or module board through bumps.

The interposer 2200 may be formed on the package substrate 2100. The interposer 2200 may be a silicon substrate in which only wiring is formed.

The one or more stacked memory devices 2300 and the processor 2400 may be formed on the interposer 2200. The stacked memory devices 2300 and the processor 2400 may be disposed on the interposer 2200 spaced apart from each other. Although four stacked memory devices 2300 are illustrated in FIG. 17, the embodiments of the present disclosure are not limited thereto, and one or more stacked memory devices may be formed on the interposer 2200.

The processor 2400 may include a memory controller and a physical interface circuit. The memory controller may be configured to control the stacked memory devices 2300. The physical interface circuit may interface between the memory controller and the stacked memory devices 2300. The physical interface circuit may be an interface circuit that converts signals transferred from the memory controller into signals suitable for use in the stacked memory devices 2300 and outputs the signals transferred from the stacked memory devices 2300 into signals suitable for use in the memory controller. The processor 2400 may be one of various processors such as a micro-processing unit (MPU), a central processing unit (CPU), a general processing unit (GPU), and a host processing unit (HPU).

Each of the stacked memory devices 2300 may include a lower chip 2310 and one or more upper chips 2320 vertically stacked on the interposer 2200. An example of the stacked memory devices 2300 formed by stacking a plurality of chips as described above may be a high bandwidth memory (HBM). Through electrodes TSV are formed between the lower chip 2310 and the upper chips 2320, through which signals (i.e., commands, addresses, and data) may be transferred between the chips.

The lower chip 2310 may include a physical interface circuit for an interface with the memory controller. Each of the upper chips 2320 may correspond to the memory device 100 described in FIG. 1. That is, each of the upper chips 2320 may include a memory core and an ECC engine. The ECC engine may correct not only an error occurring in one symbol but also an error occurring at both ends of two adjacent symbols. Therefore, it is possible to expand an error correction capability of the memory device. Depending on an embodiment, the lower chip 2310 may include an ECC engine corresponding to the ECC engine 150 of FIG. 1.

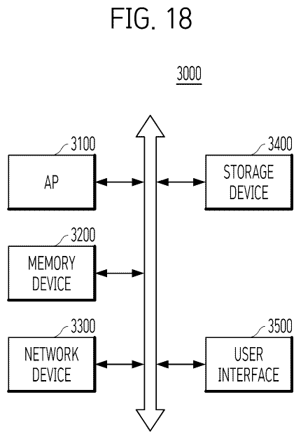

FIG. 18 is a block diagram illustrating a mobile system 3000 including a memory device 3200 according to an embodiment of the present disclosure.

Referring to FIG. 18, the mobile system 3000 may include an application processor (AP) 3100, the memory device 3200, a network device 3300, a storage device 3400, and a user interface 3500.

The application processor 3100 may drive components, an operating system (OS), or a user program included in the mobile system 3000. For example, the application processor 3100 may be provided as a system-on-chip (SoC).

The memory device 3200 may operate as a main memory, an operation memory, a buffer memory, or a cache memory of the mobile system 3000. The memory device 3200 may include a volatile random access memory such as DRAM, SDRAM, DDR SDRAM, DDR2 SDRAM, DDR3 SDRAM, LPDDR3 SDARM, LPDDR3 SDRAM, or a nonvolatile random access memory such as PRAM, ReRAM, MRAM, FRAM, etc. According to an embodiment, the memory device 3200 may correspond to the memory device 100 described in FIG. 1. That is, the memory device 3200 may include a memory core and an ECC engine. The ECC engine may correct not only an error occurring in one symbol but also an error occurring at both ends of two adjacent symbols. Therefore, it is possible to expand an error correction capability of the memory device. Depending on an embodiment, the memory device 3200 may be configured with the memory module 1000 described in FIG. 16.

The network device 3300 may communicate with external devices. For example, the network device 3300 may support wireless communication such as Code Division Multiple Access (CDMA), Global System for Mobile Communication (GSM), Wideband CDMA (WCDMA), CDMA-2000, Time Division Multiple Access (TDMA), Long Term Evolution (LTE), Wimax, WLAN, UWB, Bluetooth, Wi-Fi, etc. For example, the network device 3300 may be included in the application processor 3100.

The storage device 3400 may store data. For example, the storage device 3400 may store data received from the application processor 3100. Alternatively, the storage device 3400 may transmit the stored data to the application processor 3100. For example, the storage device 3400 may be implemented as a nonvolatile semiconductor memory device such as a phase-change RAM (PRAM), a magnetic RAM (MRAM), a resistive RAM (RRAM), a NAND flash, a NAND flash, and a three-dimensional NAND flash.

While the present invention has been described with respect to the specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A memory device comprising:
a memory core including a plurality of cell blocks grouped into a plurality of cell groups, each cell group including adjacent cell blocks disposed in a row direction and sharing sub-word line drivers with adjacent cell groups; and
an error correction circuit configured to, during a read operation, correct an error of main data in units of symbols by calculating the main data and an error correction code, which are read from the memory core, with a check matrix, each unit of symbols including data output from one cell group, or data output from cell blocks disposed at both ends of two adjacent cell groups based on a sub-word line driver shared between the two adjacent cell groups.

2. The memory device of claim 1, wherein the check matrix includes:
data matrices corresponding to the main data, each data matrix including an upper portion in which two unit matrices are arranged in a first diagonal direction and a lower portion in which two identical T^{k} companion matrices are arranged in the first diagonal direction; and
parity matrices corresponding to the error correction code, each parity matrix including an upper portion in which two unit matrices are arranged in the first diagonal direction and a lower portion in which two unit matrices or two zero matrices are arranged in the first diagonal direction.

3. The memory device of claim 2, wherein each of the unit matrices and the T^{k} companion matrices has a size of j*j, where ‘j’ is a number of bits of data output from one cell block.

4. The memory device of claim 2, wherein k values of the T^{k} companion matrices are different positive integers different from each data matrix.

5. The memory device of claim 2, wherein each of the T^{k} companion matrices is configured by a matrix including a plurality of column vectors of α^{k} to α^{k+m-1}, where ‘m’ is a number of bits of data output from one cell block, and ‘α’ includes a primitive element.

6. The memory device of claim 5, wherein the primitive element ‘α’ is set to 2.

7. The memory device of claim 1, further comprising:
an error correction code (ECC) generation circuit, during a write operation, configured to generate the error correction code by calculating the main data to be written to the memory core with the check matrix.

8. The memory device of claim 1, wherein the error correction circuit includes:
a syndrome generation circuit configured to generate a first syndrome and a second syndrome by comparing the error correction code with a calculation result obtained by calculating the main data with the check matrix;
a syndrome comparison circuit configured to generate a plurality of sub-syndromes by calculating the first syndrome and a lower portion of the check matrix, and generate a plurality of syndrome comparison signals corresponding to each of the plurality of cell blocks by comparing the plurality of sub-syndromes and the second syndrome;
an error location detector configured to generate an error location signal indicating an error location in units of symbols based on the plurality of syndrome comparison signals; and
an error corrector configured to correct an error of the main data according to the error location signal.

9. The memory device of claim 8, wherein the error location detector includes:
a symbol adder configured to generate a plurality of operational signals based on syndrome comparison signals corresponding to cell blocks included in one cell group, among the plurality of syndrome comparison signals, generate a plurality of adjacent operational signals based on syndrome comparison signals corresponding to cell blocks disposed at both ends of two adjacent cell groups, and generate a plurality of preliminary detection signals by summing the operational signals and the adjacent operational signals; and
a plurality of error detectors configured to generate the error location signal by operating the first syndrome and the plurality of preliminary detection signals.

10. The memory device of claim 1, wherein each of the cell groups includes:
odd-numbered word lines sharing odd-numbered sub-word line drivers with a cell group adjacent to each other in a first direction of the row direction; and
even-numbered word lines sharing odd-numbered sub-word line drivers with a cell group adjacent to each other in a second direction of the row direction, which is opposite to the first direction.

11. A memory device comprising:
a lower chip; and
one or more upper chips stacked over the lower chip,
wherein each of the upper chips includes:
a memory core including a plurality of cell blocks grouped into a plurality of cell groups, each cell group including adjacent cell blocks disposed in a row direction; and
an error correction circuit, during a read operation, configured to correct an error of main data in units of symbols by calculating the main data and an error correction code, which are read from the memory core, with a check matrix, each unit of symbols including data output from one cell group, or data output from cell blocks disposed at both ends of two adjacent cell groups.

12. The memory device of claim 11,
wherein each of the plurality of cell groups is configured to share sub-word line drivers with adjacent cell groups,
wherein the cell blocks disposed at both ends of two adjacent cell groups are configured to be disposed at both ends of two adjacent cell groups based on the sub-word line driver shared between the two adjacent cell groups.

13. The memory device of claim 11, wherein the check matrix includes:
data matrices corresponding to the main data, each data matrix including an upper portion in which two unit matrices are arranged in a first diagonal direction and a lower portion in which two identical T^{k} companion matrices are arranged in the first diagonal direction; and
parity matrices corresponding to the error correction code, each parity matrix including an upper portion in which two unit matrices are arranged in the first diagonal direction and a lower portion in which two unit matrices or two zero matrices are arranged in the first diagonal direction.

14. The memory device of claim 13, wherein each of the unit matrices and the T^{k} companion matrices has a size of j*j, where ‘j’ is a number of bits of data output from one cell block.

15. An error correction device comprising:
a syndrome comparison circuit configured to generate a plurality of sub-syndromes by calculating a first syndrome indicating an error pattern and a check matrix, and generate a plurality of syndrome comparison signals corresponding to each of a plurality of cell blocks by comparing the plurality of sub-syndromes and a second syndrome indicating a location of a symbol containing an error;
an error location detector configured to generate an error location signal indicating an error location in units of symbols based on the plurality of syndrome comparison signals, wherein the units of symbols include data output from one cell group among a plurality of cell groups in which adjacent cell blocks are grouped, or data output from cell blocks disposed at both ends of two adjacent cell groups; and
an error corrector configured to correct an error of a codeword output from the plurality of cell groups, according to the error location signal.

16. The error correction device of claim 15,
wherein each of the plurality of cell groups is configured to share sub-word line drivers with adjacent cell groups,
wherein the cell blocks disposed at both ends of two adjacent cell groups are configured to be disposed at both ends of two adjacent cell groups based on the sub-word line driver shared between the two adjacent cell groups.

17. The error correction device of claim 15, wherein the check matrix includes:
data matrices corresponding to main data included in the codeword, each data matrix including an upper portion in which two unit matrices are arranged in a first diagonal direction and a lower portion in which two identical T^{k} companion matrices are arranged in the first diagonal direction, where k values of the T^{k} companion matrices are different positive integers different from each data matrix; and
parity matrices corresponding to an error correction code included in the codeword, each parity matrix including an upper portion in which two unit matrices are arranged in the first diagonal direction and a lower portion in which two unit matrices or two zero matrices are arranged in the first diagonal direction.

18. The error correction device of claim 17, wherein each of the unit matrices and the T^{k} companion matrices includes a size of j*j, where ‘j’ is a number of bits of data output from one cell block.

19. The error correction device of claim 15, further comprising:
a parity calculator configured to generate a preliminary error correction code by calculating main data included in the codeword and the check matrix; and
a syndrome generator configured to generate the first syndrome and the second syndrome by comparing an error correction code included in the codeword, with the preliminary error correction code.

20. The error correction device of claim 15, wherein the syndrome comparison circuit includes:
a syndrome multiplier configured to generate the plurality of sub-syndromes respectively corresponding to the plurality of groups by performing a matrix-multiplication on the first syndrome and a lower portion of the check matrix; and
a syndrome comparator configured to generate the plurality of syndrome comparison signals by comparing the plurality of sub-syndromes with the second syndrome, respectively.

21. The error correction device of claim 20, wherein the syndrome multiplier includes:
data multipliers configured to generate lower sub-syndromes by performing a matrix-multiplication on lower bits of the first syndrome and T^{k} companion matrices, and generate upper sub-syndromes by performing a matrix-multiplication on upper bits of the first syndrome and the T^{k} companion matrices, where k values of the T^{k} companion matrices are different positive integers different from each data matrix; and
parity multipliers configured to generate the lower sub-syndromes by performing a matrix-multiplication on the lower bits of the first syndrome and a unit matrix or a zero matrix, and generate the upper sub-syndromes by performing a matrix-multiplication on the upper bits of the first syndrome and the unit matrix or the zero matrix.

22. The error correction device of claim 15, wherein the error location detector includes:
a symbol adder configured to generate a plurality of operational signals based on syndrome comparison signals corresponding to cell blocks included in one cell group, among the plurality of syndrome comparison signals, generate a plurality of adjacent operational signals based on syndrome comparison signals corresponding to cell blocks disposed at both ends of two adjacent cell groups, and generate a plurality of preliminary detection signals by summing the operational signals and the adjacent operational signals; and
a plurality of error detectors configured to generate the error location signal by operating the first syndrome and the plurality of preliminary detection signals.

23. A memory device comprising:
a memory core; and
an error correction circuit, during a read operation, configured to correct an error of main data in units of symbols by calculating the main data and an error correction code, which are read from the memory core, with a check matrix,
wherein the check matrix includes:
data matrices corresponding to the main data, each data matrix including an upper portion in which two unit matrices are arranged in a first diagonal direction and a lower portion in which two identical T^{k} companion matrices are arranged in the first diagonal direction, where k values of the T^{k} companion matrices are different positive integers different from each data matrix; and
parity matrices corresponding to the error correction code, each parity matrix including an upper portion in which two unit matrices are arranged in the first diagonal direction and a lower portion in which two unit matrices or two zero matrices are arranged in the first diagonal direction.
